(19) United States
(12) Patent Application Publication
(10) Pub. No.: US 2013/0264544 A1
(43) Pub. Date: Oct. 10, 2013

(54) NANOWIRE FIELD-EFFECT DEVICE WITH MULTIPLE GATES

(71) Applicants: Siegfried F. Karg, Adliswil (CH); Kirsten Emilie Moselund, Zurich (CH)

(72) Inventors: Siegfried F. Karg, Adliswil (CH); Kirsten Emilie Moselund, Zurich (CH)

(21) Appl. No.: 13/995,228

(22) PCT Filed: Nov. 30, 2011
(86) PCT No.: PCT/IB2011/055369

§ 371 Date: Jun. 18, 2013

(30) Foreign Application Priority Data
Dec. 22, 2010 (EP) 10196435.1

(51) Int. Cl. H01L 29/775; H01L 29/66

(52) U.S. Cl. CPC H01L 29/775; H01L 29/66439
USPC 257/24; 438/268

(57) ABSTRACT

The present invention relates to a semiconductor device (1) comprising: at least a nanowire (2) configured to comprise: at least a source region (3) comprising a corresponding source semiconductor material, at least a drain region (4) comprising a corresponding drain semiconductor material and at least a channel region (5) comprising a corresponding channel semiconductor material, the channel region (5) being arranged between the source region (3) and the drain region (4), at least a gate electrode (6) that is arranged relative to the nanowire (2) to circumferentially surround at least a part of the channel region (5), and at least a strain gate (7) that is arranged relative to the nanowire (2) to circumferentially surround at least a part of a segment of the nanowire (2), the strain gate (7) being configured to apply a strain to the nanowire segment (8), thereby to facilitate at least an alteration of the energy bands corresponding to the source region (3) relative to the energy bands corresponding to the channel region (5).

### FIELD OF THE INVENTION

The present invention relates to a semiconductor device and a method of fabrication therefor.

### BACKGROUND OF THE INVENTION

Tunnel field-effect transistors (FETs) may be used in several applications, including high-speed switching and logic circuits. Unlike the case for other types of FETs, an inverse sub-threshold slope of tunnel FETs is not limited to the 60 mV/dec at room temperature as determined by the Boltzmann tail of the Fermi statistics. Thus, tunnel FETS may potentially have a faster turn-on than previously-proposed devices, i.e. the bias range to facilitate the transition from an “ON”, conducting state, to an “OFF”, non-conducting state is smaller than is the case for previously-proposed devices, and both threshold and operating voltages may be reduced without a corresponding deterioration of device performance. This makes tunnel FETs particularly suitable for applications where reduced power consumption is desired.

Until recently, the scaling of MOSFET dimensions was sufficient to achieve improved device performance. Only recently, some of the limitations associated thereto, for example, sub-threshold swing, have become apparent as inhibiting further voltage scaling. As a consequence, devices having a relatively reduced power consumption compared to MOSFETs have been studied and, in this regard, tunnel FETs have emerged as a promising candidate.

A problem associated with silicon-based tunnel FETs is that the relatively large band-gap of silicon causes a reduced band-to-band tunneling efficiency of carriers and, therefore, a relatively low “ON” current of such a device, i.e. when the device is in a conducting state. This may cause an increased delay in, for example, performing logic operations where a relatively high ON current is desirable.

It is known that the application of strain to a semiconductor may influence its band-gap width and/or tunneling mass. Studies have also shown that the application of strain on nanowires may influence the band-structures of the semiconductor from which the nanowires are fabricated to an even larger extent than if that semiconductor formed the basis of, for example, planar devices and/or structures. In this regard, reference is made to Sajjad et.al, Journal of Applied Physics, Volume 105, page 044307, 2009, wherein it is reported that the band-gap in Si(100) nanowires is considerably reduced by the application of both tensile and compressive stress to the nanowires and that the hole effective mass is also reduced by such an action. The effect of strain on III-V-based systems has generally been studied to a lesser extent than, for example, Si-based systems. In this regard, it has been shown that the band-gap width of gallium arsenide (GaAs) is increased by approximately 100-200 mV at realistically obtainable strain values of 2-3%.

With respect to tunnel FETs, it is known that the band-to-band tunneling efficiency may be improved by scaling down the band-gap of the semiconductor material system on which the tunnel FET is based. However, if this is done throughout the entire structure of the tunnel FET, i.e. for all of the source, drain and gate of the tunnel FET, then this may lead to an increased leakage current, I_{OFF}, which may, for example, impact the reliability and controllability with which the tunnel FET may be switched from a conducting ON state to a non-conducting OFF state and vice versa, thus making it unattractive for high-speed switching applications. In particular, as the main field of application of the tunnel FET is deemed to be where reduced power consumption is desirable, such a leakage current would adversely contribute to the overall power consumption, thereby off-setting the potential benefit of the tunnel FET.

In order to improve the band-to-band tunneling efficiency, it has been proposed to base the tunnel FET on a heterostructure material system whereby only the source is replaced with a semiconductor having a relatively smaller band-gap than Si. In this regard, reference is now made to Verhulst et.al, IEEE Electron Device Letters, Volume 29, pages 1-4, 2008, wherein such a nanowire-based heterostructure n-tunnel FET and p-tunnel FET are respectively disclosed. For improved tunneling efficiency of the n-tunnel TFET, Verhulst et.al report that the band discontinuity at the source-channel junction should be in the valence band, this being obtained by, for example, using silicon-germanium (SiGe) as the semiconductor material for the source and Si for the channel in the n-tunnel TFET. Conversely, for the p-tunnel TFET, it is reported that the band discontinuity at the source-channel junction should be in the conduction band for improved tunneling efficiency, this being obtained by, for example, fabricating the source from indium gallium arsenide (InGaAs) on a Si-based channel.

Although tunnel FETs fabricated from heterostructures theoretically present favourable characteristics in terms of band alignment, the lattice mismatch between the different materials constituting the heterostructures may result in the formation of defects at the interface thereof. If this interface is located at or in the vicinity of the tunnel junction, i.e. at the source-channel interface, then this may deteriorate tunneling efficiency, as carriers are likely to participate in trap-assisted tunneling rather than direct band-to-band tunneling.

In previously-proposed devices, the tunnel junction is fabricated using impurity doping. In this case, a technical challenge may be to make the tunnel junction as abrupt as possible, this condition being conducive to the occurrence of tunneling of carriers across the tunnel junction. A factor that may contribute to such a challenge is that the thermal processing commonly used in impurity doping may tend to “smear out” the tunnel junctions across which tunneling of the carriers occurs since the thermal treatment causes diffusive widening of the doped area and process incompatibilities. Where the tunnel FET is based on a vertical nanowire process, for example, a further challenge would be experienced in creating an abrupt tunnel junction at the base of the nanowire. Furthermore, in some materials, the chemical doping of both polarities may be challenging, for example, due to difficulties associated with incorporating atoms of a desired doping during growth.

Reference is now made to Lee et.al, Applied Physics Letters, Volume 85, pages 145-147, 2004, wherein it is reported that electrostatic doping may alleviate some of the drawbacks associated with impurity doping particularly in relation with materials such as III-V systems which have relatively narrow temperature constraints and where achieving sufficient activated dopants of one or both polarities by impurity doping and/or other previously-proposed methods is challenging compared to the case for Si. However, this document is concerned with implementing electrostatic doping in planar devices, specifically MOSFETs. It contains no teaching on the use of electrostatic doping in conjunction with tunnel FETs and, more specifically, vertical processes and/or devices such as, for example, vertical nanowire tunnel FETs.

### SUMMARY OF THE INVENTION

According to an embodiment of a first aspect of the present invention, there is provided a semiconductor device comprising: at least a nanowire configured to comprise: at least a source region comprising a corresponding source semiconductor material, at least a drain region comprising a corresponding drain semiconductor material and at least a channel region comprising a corresponding channel semiconductor material, the channel region being arranged between the source region and the drain region, at least a gate electrode that is arranged relative to the nanowire to circumferentially surround at least a part of the channel region, and at least a strain gate that is arranged relative to the nanowire to circumferentially surround at least a part of a segment of the nanowire, the strain gate being configured to apply a strain to the nanowire segment, thereby to facilitate at least an alteration of the energy bands corresponding to the source region relative to the energy bands corresponding to the channel region. Due to the strain application feature in an embodiment of the present invention, an alteration of the energy-bands corresponding to the source region relative to the energy-bands corresponding to the channel region may be facilitated. Particularly, by way of the strain application to the nanowire segment, the band-gap of the semiconductor material corresponding thereto may be altered and, more desirably, reduced. This has the corresponding effect of altering the band-alignment of the energy-bands corresponding to the source region and the energy-bands corresponding to the channel region—desirably, the band-alignment between the energy-bands of the source region and the channel region is altered such that the band-gap of the source region is reduced compared to that of the channel region. In this way, the barrier height of the tunnel junction between the source region and the channel region may be reduced, thereby improving the tunneling efficiency of carriers across the tunnel junction in an embodiment of the present invention as compared to previously-proposed devices. A tunneling mass of carriers across the tunneling junction may be altered in addition to, or independently of, the band-gap reduction of the source region by the strain application, which facilitates an improved tunneling rate of carriers across the tunnel junction, thereby contributing to an improved tunneling efficiency of an embodiment of the present invention compared to previously-proposed devices. Alteration of the tunneling mass of the carriers may be facilitated by altering a curvature of the energy-bands corresponding to the source region relative to the curvature of the energy-bands corresponding to the channel region.

Preferably, the strain gate is configurable to apply a strain gate bias to the nanowire segment, thereby to facilitate electrostatic doping of the nanowire segment. An embodiment of the present invention may be configured to apply a strain gate bias to the nanowire segment via the strain gate. By appropriate selection of the strain gate bias, the semiconductor material corresponding to the nanowire segment may be doped with a desired polarity of carriers. In this way, electrostatic doping of the nanowire segment may be facilitated. An advantage associated with electrostatic doping according to an embodiment of the present invention is that doping may be performed without substantially any chemical impurities and/or implantation process. A further advantage associated with electrostatic doping is it entails no thermal treatment for the activation of dopants—such thermal treatment may cause diffusive widening of the doped areas and, therefore, a tunnel junction with a “smeared” tunnel junction. The latter feature is, of course, undesirable since it may cause a deterioration of the tunneling efficiency of carriers across the tunnel junction. Thermal treatments for doping also cause process incompatibilities—this problem is bypassed in electrostatic doping. Furthermore, in a vertical process, the doping problems associated thereto, such as, for example, the difficulty in implanting dopant in the nanowire, may be bypassed by electrostatic doping according to an embodiment of the present invention. For some semiconductor material systems, such as, for example, III-V compound semiconductors, electrostatic doping may present relatively significant design and/or processing advantages since: the impurity doping of one or both polarities of III-V semiconductor systems may be challenging as compared to the case for Si; it may be challenging to achieve sufficient activated dopants of either polarity in such material systems by known doping methods and such material systems have relatively narrow temperature constraints.

Preferably, the strain gate comprises a material that is chosen to provide a specific strain value to the nanowire segment and to have a work-function value in accordance with a polarity of the semiconductor device. This feature provides the advantage that the strain gate may be configured to perform the dual function of strain application and electrostatic doping of the nanowire segment.

Preferably, the nanowire is substantially vertically aligned. Since the strain gate may be used to perform the dual function of applying a strain and electrostatic doping, fabrication of an embodiment of the present invention, particularly when implemented by way of a vertically-aligned nanowire, is made simpler compared to previously-proposed devices. Furthermore, problems pertaining to spatial constraints may be reduced since the strain gate extends in the axial direction of the nanowire. Certain dimensions and/or structures associated with an embodiment of the present invention may be better controlled by the implementation thereof by way of a vertically-aligned nanowire rather than a planar configuration. Where an embodiment of the present invention is implemented by a vertical nanowire, a strain gate spacer layer is Preferably formed below the strain gate, this feature providing the advantage of a reduced parasitic capacitance.

Preferably, at least a gate dielectric is provided conformally on an outer surface of the nanowire. A dielectric material that facilitates the confinement of the respective carriers in at least the source region and the channel region, such that an abruptness of the tunneling junction created therebetween is increased, may be chosen for the gate dielectric. This condition may be generally satisfied by a dielectric material having a dielectric constant relative to a vacuum that is greater in magnitude than 4. An example of such a material is silicon dioxide or hafnium oxide.

Preferably, in an embodiment of the present invention, the strain gate comprises a metal. Where an embodiment of the present invention is operated such that the strain gate is used to electrostatically dope the semiconductor material corresponding to the nanowire segment, this being done by the application of a strain gate bias to the strain gate, in addition to applying a strain to the nanowire segment, the strain gate is chosen to comprise a conductive material, such as, for example, a metal. In this regard, tantalum nitride (TaN) may be used for the strain gate material in an embodiment of the present invention.

Preferably, an isolation layer is provided between the gate electrode and the strain gate. The isolation layer electrically isolates the gate electrode from the strain gate and may, for example, comprise a dielectric material. In this way, electrical shorting of the gate electrode and the strain gate may be avoided and the reliability with which an embodiment of the present invention operates may be improved.

Preferably, in an embodiment of the present invention, the source semiconductor material, the drain semiconductor material and the channel semiconductor material are the same. This feature may provide the advantages of reducing fabrication complexity and also there are potentially no defects at the interfaces between the different regions of the nanowire corresponding to these materials. In this regard, the source semiconductor material, the drain semiconductor material and the channel semiconductor material may be selected to comprise one of: a Group IV element and a binary compound thereof.

Alternatively, in an embodiment of the present invention, the source semiconductor material is different from at least the channel semiconductor material. In this case, there may be defects associated with the lattice mismatch between the source semiconductor material and the channel semiconductor material at the source region/channel region interface. However, the disadvantages associated thereto, particularly a deterioration of the tunneling efficiency, may be at least partially be compensated for by the strain application feature of an embodiment of the present invention. In this case, the source semiconductor material is selected to comprise one of: a Group III-V material system, a binary, ternary and quarternary compound thereof. Alternatively, the source semiconductor material may be selected to, for example, comprise a Group IV binary compound, such as SiGe.

Preferably, an embodiment of the present invention comprises one of: a tunnel FET, a MOSFET and an impact ionization FET. The advantages of an embodiment of the present invention, namely, to facilitate the reduction in band-gap of the semiconductor material corresponding to the nanowire segment and/or a reduction in the tunneling mass of the carriers may be beneficial: for the source-injection velocity in nanowire metal-oxide-semiconductor field-effect transistors (MOSFETs); the tunneling efficiency in tunnel FETs and the impact ionization velocity in impact ionization FETs.

Corresponding method aspects are also provided and so according to an embodiment of a second aspect of the present invention, there is provided a method for fabricating a semiconductor device comprising the steps of: providing at least a nanowire that is configured to comprise: at least a source region comprising a corresponding source semiconductor material, at least a drain region comprising a corresponding drain semiconductor material and at least a channel region comprising a corresponding channel semiconductor material, the channel region being arranged between the source region and the drain region; forming at least a gate electrode that is arranged relative to the nanowire to circumferentially surround at least a part of the channel region; forming at least a strain gate that is arranged relative to the nanowire to circumferentially surround at least a part of a segment of the nanowire, and configuring the strain gate to apply a strain to the nanowire segment, thereby to facilitate at least an alteration of the energy bands corresponding to the source region relative to the energy bands corresponding to the channel region.

Any of the device features may be applied to the method aspect of the present invention and vice versa. Features of one aspect of the invention may be applied to another aspect of the invention. Any disclosed embodiment may be combined with one or several of the other embodiments shown and/or described. This is also possible for one or more features of the embodiments.

### BRIEF DESCRIPTION OF THE DRAWINGS

Reference will now be made, by way of example, to the accompanying drawings in which:

FIG. 1 schematically illustrates an embodiment of the present invention;

FIGS. 2a and 2b schematically illustrate the principle of band-gap shrinkage and electrostatic doping in an embodiment of the present invention;

FIGS. 3a, 3b and 3c schematically illustrate an embodiment of the present invention according to different modes of operation, and

FIGS. 4a, 4b, 4c and 4d schematically illustrate an embodiment according to a method aspect of the present invention.

### DETAILED DESCRIPTION OF PREFERRED EMBODIMENTS

Within the description, the same reference numerals or signs have been used to denote the same parts or the like.

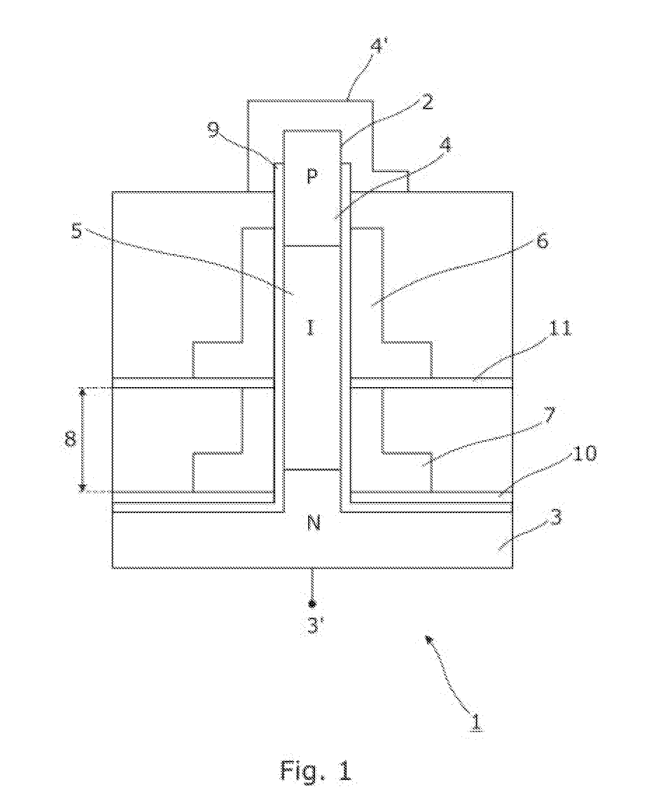

Reference is now made to FIG. 1, which schematically illustrates an embodiment according to a device aspect of the present invention.

As can be seen from FIG. 1, an embodiment of the present invention comprises a tunnel FET 1 that may be implemented by way of a nanowire 2. In this particular example of an embodiment of the present invention, the nanowire 2 is substantially vertically aligned and grown/etched out of an intrinsic semiconductor substrate. The nanowire 2 is configured to have at least three distinct regions: at least a source region 3 comprising a corresponding source semiconductor material, at least a drain region 4 comprising a corresponding drain semiconductor material and at least a channel region 5 comprising a corresponding channel semiconductor material that is disposed between the source region 3 and the drain region 4. As can be seen from FIG. 1, an embodiment of the present invention may be configured such that the carriers in the source region 3 have a different polarity from the carriers in the drain region 4, so if the source region 3 is n-type doped than the drain region 4 is p-type doped and vice versa. In this way, the polarity of the device is determined. Thus, an embodiment of the present invention as shown in FIG. 1 is a p-tunnel FET since the source region 3 is shown as n-type doped and the drain region 4 is shown as p-type doped. In the present example, the channel semiconductor material corresponding to the channel region 5 is configured to substantially have an intrinsic carrier concentration. Electrodes corresponding to the different regions of the nanowire 2 are also provided in an embodiment of the present invention. Coupled to the source region 3 and the drain region 4 are source and drain electrodes, 3’ and 4′ respectively, the drain electrode 4′ having been generally shown as a top-contact in FIG. 1. A gate electrode 6 corresponding to the channel region 5 is also provided and is arranged relative to the nanowire 2 to circumferentially surround at least a part or all of the channel region 5.

In an embodiment of the present invention, there is further provided at least a strain gate 7 that is arranged relative to the nanowire 2 to circumferentially surround at least a part of a segment of the nanowire 2. By way of the strain gate 7, a strain is applied to the semiconductor material enclosed by the nanowire segment 8. As can be seen from FIG. 1, in an embodiment of the present invention, the nanowire segment 8 corresponds to a part of the channel region 5 that is disposed substantially adjacent to the source region 3.

In an embodiment of the present invention, the strain gate 7 is configurable to apply a strain gate bias to the nanowire segment 8. In this way, electrostatic doping of the semiconductor material corresponding to the nanowire segment 8 may be facilitated since, by selecting the strain gate bias applied to the strain gate 7, the semiconductor material corresponding to the nanowire segment 8 may be doped with a desired polarity of carriers. By the application of strain to the nanowire segment 8 and electrostatically doping the semiconductor corresponding thereto, the part of the channel region 5 that is disposed substantially adjacent to the source region 3, which the nanowire segment 8 corresponds to, effectively becomes a part of the source region 3.

Due to the strain application feature in an embodiment of the present invention, an alteration of the band-alignment of the energy-bands corresponding to the source region 3 and the channel region 5 may be facilitated. Particularly, by way of the strain application to the nanowire segment 8, the band-gap of the semiconductor material corresponding thereto may be altered and, more desirably, reduced. This has the overall effect that the band-gap of the source region 3 is reduced compared to that of the channel region 5, which has the effect of reducing the barrier height of the tunnel junction between the source region 3 and the channel region 5, thereby improving the tunneling efficiency of carriers across the tunnel junction in an embodiment of the present invention as compared to previously-proposed devices. A tunneling mass of carriers across the tunneling junction may be altered in addition to, or independently of, the band-gap reduction of the source region 3 by the strain application, which facilitates an improved tunneling rate of carriers across the tunnel junction, thereby contributing to an improved tunneling efficiency of an embodiment of the present invention compared to previously-proposed devices.

By way of the strain application feature, a performance of an embodiment of the present invention in a specific application may be tailored. For example, where increased current output of a tunnel FET is desired, it is desirable to reduce the band-gap width of the source semiconductor material and the tunneling mass of the carriers to facilitate increased tunneling probability. Depending on the choice of the source semiconductor material and a crystalline orientation thereof, an embodiment of the present invention may be configured to apply a tensile strain or a compressive strain so as to achieve the desired performance. Another example is where reduced power consumption of a tunnel FET is desired. In this particular case, the strain application feature of an embodiment of the present invention is configured thereby to achieve band-alignment conducive to tunneling with a relatively lower gate bias than in previously-proposed devices.

Where the strain gate 7 performs the dual function of strain application and the electrostatic doping in an embodiment of the present invention, the strain is self-aligned to the junction profile. Since both the strain applied by the strain gate 7 and the doping induced by the electrical bias applied to the strain gate 7 is applied to the same region, i.e. the nanowire segment 8, the doping profile and the strain profile are self-aligned. This provides the advantage that further processing steps to correct for any misalignment between the doping profile and the strain profile need not be conducted, such processing steps being undesirable from the viewpoint that they may introduce errors, which may deteriorate the performance of an embodiment of the present invention.

In an embodiment of the present invention, the strain gate 7 is chosen so as to comprise a material that provides a specific strain value to the nanowire segment 8 and to have a work-function value in accordance with a polarity of an embodiment of the present invention. In this regard, the strain gate 7 is chosen to comprise a metal, for example, TaN, which may be deposited conformally by atomic layer deposition (ALD). Alternatively, the strain gate 7 may comprise other nitrides such as titanium nitride (TiN) or hafnium nitride (HfN). Other materials that may be used for the strain gate 7 include carbon or amorphous carbon, these particular materials having the capability to exert a tensile strain. Where an embodiment of the present invention is operated without engaging the electrostatic doping feature, i.e. where the strain gate only performs the function of strain application to the nanowire segment 8, the doping of the nanowire 2 having been effectuated with other doping methods, for example, implantation or during growth of the nanowire 2, the strain gate 7 need not comprise a conductive material.

The strain gate 7 is arranged relative to the nanowire segment 8 such that the strain and electrostatic doping functions may be performed. In this regard, the strain gate 7 may be arranged to circumferentially surround at least a part of the nanowire segment 8 or to extend all the way around the nanowire segment 8. The strain gate 7 may not be entirely continuous or homogeneous—its form may be patterned or have random discontinuities.

In an embodiment of the present invention, the same semiconductor material may be used for the source semiconductor material, the channel semiconductor material and the drain semiconductor material, such as, a Group IV element or a binary compound thereof. Specific examples of the semiconductor material that may be used in this case include: carbon (C), Si, Ge, SiₓGe₁₋ₓ, and SiₓC₁₋ₓ.

In another embodiment of the present invention, the tunneling junction may be formed from heterostructures, i.e. the source semiconductor material is different from at least the channel semiconductor material, for example, the source semiconductor material may be chosen to comprise one of: a Group III-V compound semiconductor, a binary, ternary and quarternary compound thereof. An example of heterostructures used for an embodiment of the present invention is gallium antimonide (GaSb) for the source region 3 and indium arsenide (InAs) or indium gallium arsenide (InGaAs) for the channel region 5/drain region 4. Other examples of materials that may be used for the source region 3 include: GaAs, InAs, InGaAs, indium antimonide (InSb) and GaSb.

Other features of an embodiment of the present invention include a gate dielectric 9 that is conformally formed on an outer surface of the nanowire 2 before the formation of the gate electrode 6 and strain gate 7 thereon. The gate dielectric 9 may, for example, be silicon dioxide and hafnium dioxide. However, an embodiment of the present invention is not limited to the use of such materials and, in fact, any other dielectric material which facilitates the confinement of the respective carriers in at least the source region 3 and the channel region 5, such that an abruptness of the tunneling junction created therebetween is increased, may be chosen for the gate dielectric 9. Generally, in an embodiment of the present invention, the gate dielectric 9 is chosen to comprise a dielectric material having a dielectric constant relative to a vacuum that is greater in magnitude than 4. As shown in FIG. 1, and where an embodiment of the present invention is implemented by way of a vertical nanowire process, a strain gate spacer layer 10 may be provided below the strain gate 7, i.e. to underlie the strain gate 7, this feature providing the advantage of a reduced parasitic capacitance. In order to electrically isolate the gate electrode 6 and the strain gate 7, an isolation layer 11 is provided therebetween in an embodiment of the present invention. The isolation layer 11 may, for example, be provided in a radial or axial direction. It is desirable that the positioning of the gate electrode 6 relative to the source region 3 be such as to enable coupling of the gate electrode 6 to the interface between the source region 3 and the channel region 5, i.e. it should not be physically removed from such an interface by more than a few tens of nanometers, which basically puts an upper limit on the thickness of the isolation layer 11. In an embodiment of the present invention, the strain gate spacer layer 10 underneath the strain gate 7 and the isolation layer 11 between the strain gate 7 and the gate electrode 6 need not comprise the same dielectric material. In fact, for the isolation layer 11, 7-10 nm of aluminium oxide (Al₂O₃) is deposited in an embodiment of the present invention.

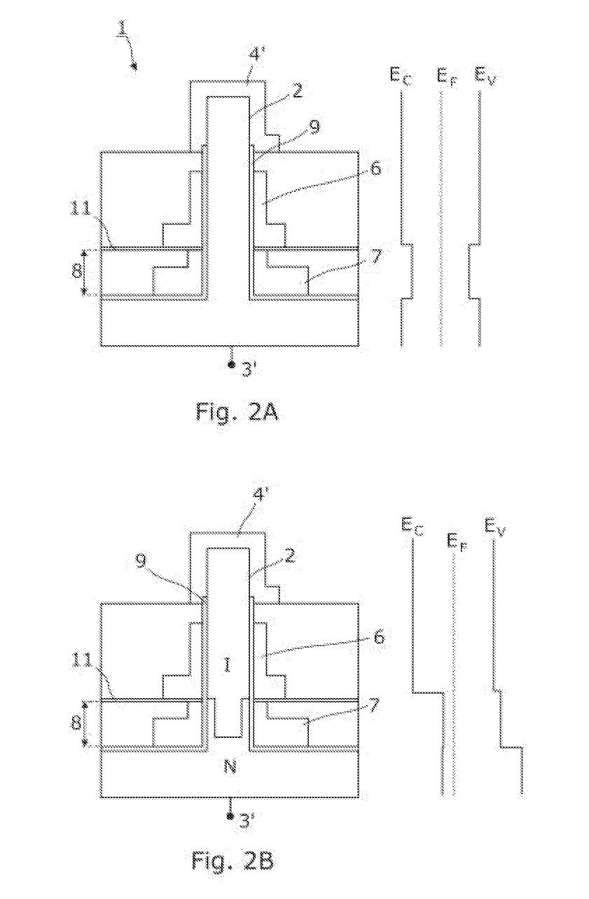

Reference is now made to FIGS. 2a and 2b, which schematically illustrate the principles of band-gap shrinkage and electrostatic doping in an embodiment of the present invention. In FIG. 2a, the strain gate 7 is not configured to apply a strain gate bias to the nanowire segment 8. It can be seen from the region of the energy band-diagram corresponding to the nanowire segment 8 that the band-gap of the semiconductor material corresponding to the nanowire segment 8 is reduced compared to the other parts of the channel region 5, for example, where the gate electrode 6 is present thereon. In this way, the tunneling efficiency of carriers across the tunnel junction may be improved in an embodiment of the present invention as compared to previously-proposed devices.

FIG. 2b schematically illustrates the scenario where the strain gate 7 is configured to perform the dual function of band-gap shrinkage and electrostatic doping in an embodiment of the present invention. The principle of band-gap shrinkage is as hereinbefore described with reference to FIG. 2a. In FIG. 2b, in contrast to the scenario shown In FIG. 2a, the source region 3 is shown as n-type doped by the Fermi Level, E_{f}, being displaced closer to the conduction band, E_{c}, than the valence band, Eᵥ in the region of the band-diagram corresponding to the source region 3. By the application of a positive strain gate bias to the nanowire segment 8 via the strain gate 7, in addition to strain application, n-type doping of the source region 3 may be done.

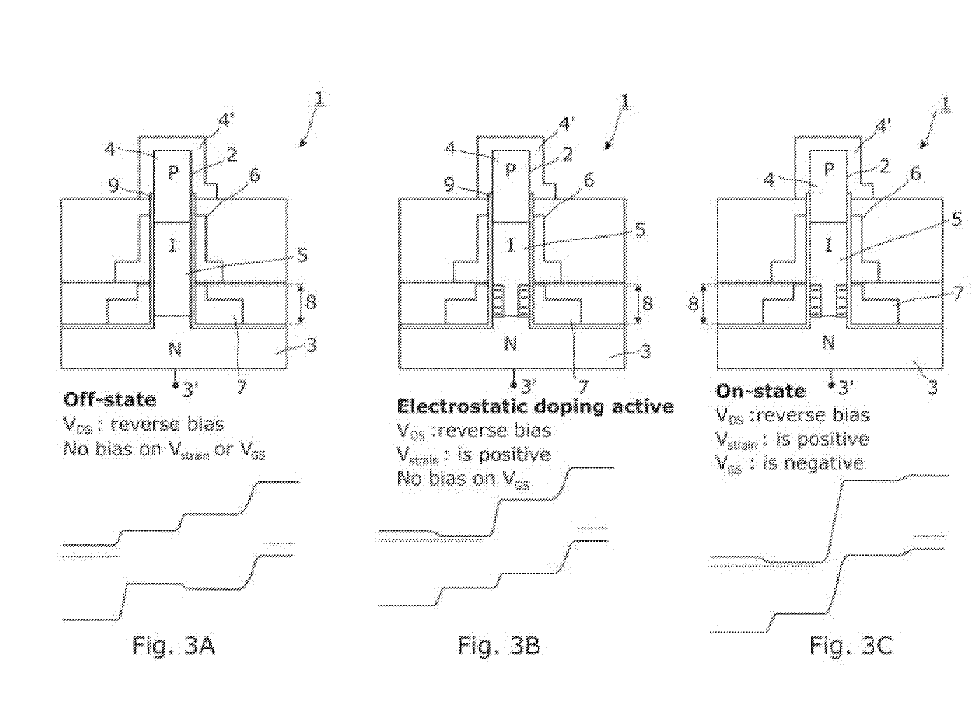

Reference is now made to FIGS. 3a, 3b and 3c which depict a p-tunnel FET according to an embodiment of the present invention in different modes of operation and corresponding energy-band diagrams. In these figures, the energy-band diagrams as extending from left to right correspond to the “p-i-n” junction according to an embodiment of the present invention as extending from the bottom upwards. In this embodiment, the strain gate 7 is configured to perform the dual function of bandgap shrinkage through strain and source doping through electrostatic doping.

FIG. 3a depicts a p-tunnel FET according to an embodiment of the present invention in one “OFF” state, i.e. with substantially no occurrence of tunneling. In this mode of operation, no bias is applied on the strain gate 7 and the gate electrode 6, i.e. Vₛₜᵣₐᵢₙ, V_{gs}=0, and a reverse bias is applied on V_{ds} i.e. a negative bias is applied on the drain electrode 4′ relative to the source electrode 3′. Since no bias is applied to the strain gate 7, the electrostatic doping function according to an embodiment of the present invention is disabled. As can be seen from the energy-band diagram of FIG. 3a, the band-gap width of the semiconductor material corresponding to the nanowire segment 8 is reduced compared to, for example, where the gate electrode 6 is present on the outer surface of the nanowire 2 and/or if the strain gate 7 would be absent as would be the case in previously-proposed devices. In an embodiment of the present invention, the alteration of the band-gap width of the semiconductor material in the nanowire segment 8 may be done by tailoring the strain applied via the strain gate accordingly.

Reference is now made to FIG. 3b, which depicts the scenario where the electrostatic doping function is activated in addition to strain application in a p-tunnel FET according to an embodiment of the present invention. In this mode of operation and in this particular example, no bias is applied on the gate electrode 6, a reverse bias is applied on V_{ds} and a positive bias is applied to the strain gate 7. By the application of a positive Vₛₜᵣₐᵢₙ, negative charge is induced on the inner walls of the nanowire segment 8 and, in this way, n-type doping may be effectuated in the nanowire segment 8. Electrostatic n-type doping of the nanowire segment 8 is depicted in the energy-band diagram of FIG. 3b in that the Fermi level is displaced closer to the conduction band in that part of the energy-band diagram corresponding to the nanowire segment 8. Strain application to the nanowire segment 8 is depicted by a reduction in the band-gap width of the energy-bands corresponding to the nanowire segment 8, this region effectively becoming a part of the source region 3 due to the dual application of electrostatic doping and strain application to the nanowire segment 8. Since V_{gs}=0 in the present example, no tunneling of carriers occurs between the tunneling junction, i.e. from the source region 3, n-doped, to the channel region 5, so the tunnel FET is still in an “off” mode. Electrostatic doping may be enabled even though the tunnel FET is an “off” mode. However, it is desirable to disable the electrostatic doping function in an embodiment of the present invention when in an off mode so that the benefit of an increased channel length may be derived and a leakage current, I_{OFF}, may be reduced.

Reference is now made to FIG. 3c, which depicts a p-tunnel FET according to an embodiment of the present invention in an “ON” state, i.e. with the occurrence of tunneling between the conduction band of the source region 3, n-type doped, and the valence band of the channel region 5. In this mode of operation and in this particular example, Vₛₜᵣₐᵢₙ is positive, V_{gs} is negative and a reverse bias is applied on V_{ds}. For Vₛₜᵣₐᵢₙ is positive and as for the case shown in FIG. 3b, negative charges are induced on the inner walls of the nanowire segment 8 where the strain gate 7 is present thereon, i.e. electrostatic doping of the nanowire segment 8 is facilitated. Application of a negative V_{gs} facilitates the alignment of the valence band in the channel region 5 and the conduction band in the source region 3, thereby causing the tunneling of carriers therebetween. Since the tunneling barrier height between the source region 3 and the channel region 5 is substantially reduced, this being facilitated by the reduction in band-gap width in the nanowire segment 8 corresponding to the source region 3, the tunneling efficiency in an embodiment of the present invention is improved as compared to previously-proposed devices.

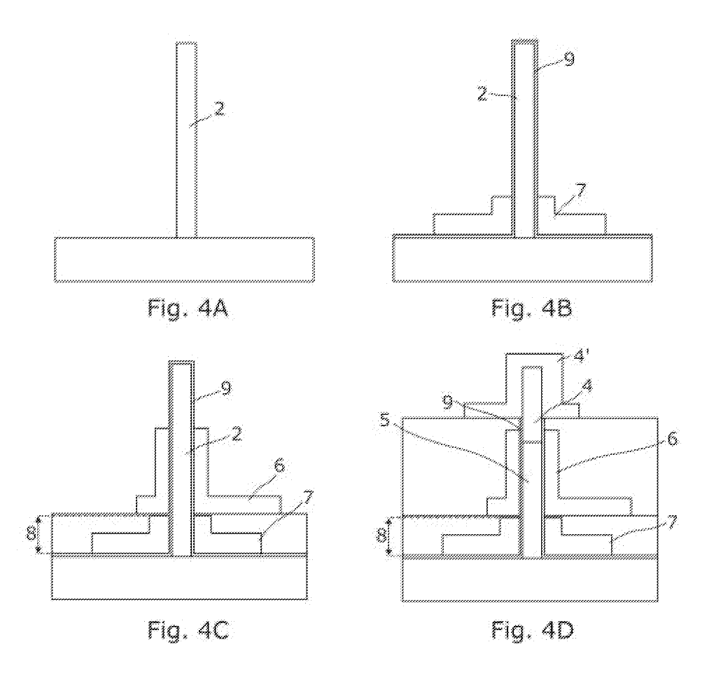

Reference is now made to FIGS. 4a to 4d, which schematically illustrate the steps according to an embodiment of a method aspect of the present invention.

Referring to FIG. 4a, a substrate comprising semiconductor material, which is doped so as to provide an ohmic contact and supply carriers for the electrostatic doping, is provided. A nanowire 2 that is substantially vertically aligned is fabricated on the substrate by a “bottom-up” growth process or a “top-down” etching process on the substrate. After formation of the nanowire 2, it may have an intrinsic carrier concentration or it may have a doping profile extending in the axial direction such that, for example, a reduced resistance drain electrode 4′ may be provided.

Referring to FIG. 4b, a gate dielectric 9 is deposited conformally on the outer surface of the nanowire 2. A strain gate 7 is then formed on the surface of the nanowire 2 modified by the gate dielectric 9 on at least a segment of the nanowire 2, hereinbefore referred to as the nanowire segment 8. As earlier described, the strain gate 7 is formed thereby to introduce a strain on the nanowire segment 8, this strain being either compressive strain or a tensile strain. The strain gate 7 may then be etched to a desired height and/or patterned. In order that the strain gate 7 may be able to perform the dual function of strain application and electrostatic doping, it desirably comprises conductive material, such as, for example, TaN. Although not depicted in FIG. 4b, where an embodiment of the present invention is implemented by way of a vertical nanowire 2, a strain gate spacer layer 10 may be deposited below the strain gate 7 thereby to provide the advantage of a reduced parasitic capacitance.

As shown in FIG. 4c, a planarization layer is deposited on the strain gate 7, thereby to enable the deposition of further features of an embodiment of the present invention. As can be seen from FIG. 4c, a gate electrode 6 is deposited on an outer surface of the nanowire 2 to circumferentially surround at least a part of the channel region 5, the gate electrode 6 being disposed above the strain gate 7 in this particular example of a method aspect of an embodiment of the present invention. Although not depicted in FIG. 4c, an isolation layer 11 comprising a dielectric material is deposited between the gate electrode 6 and the strain gate 7, thereby to electrically isolate them. Alternatively, the gate electrode 6 may be deposited thereby to overlap the strain gate 7 so as to avoid a gate underlap. The gate electrode 6 is then etched to a desired height and may also be patterned.

Reference is now made to FIG. 4d which depicts the formation of a further planarization layer on the gate electrode 6, thereby to facilitate the formation of further features pertaining to an embodiment of the present invention. The gate dielectric 9 is removed from the outer surface of the nanowire 2 where the nanowire 2 extends past the planarization layer that is formed after the provision of the gate electrode 6 on the nanowire 2. A further step to dope the region of the nanowire 2 corresponding to the drain region 4 may then be done if the drain region is undoped. Formation of the drain electrode 4′ by the deposition of a contact metal and patterning thereof may then be done. In the present example, doping of the drain region 4 is done substantially after all or most of the technical features of an embodiment of the present invention have been fabricated; however, Preferably, doping of the drain region 4 is done earlier on in the processing line of an embodiment of the method aspect of the present invention since the relatively large thermal budget for activation at the end of the processing line in order to perform the doping of the drain region 5 may not be particularly desirable.

An embodiment of the present invention has been hereinbefore described with reference to a tunnel FET. It is, however, not restricted thereto and may be extended to other types of field-effect transistors such as, for example, MOSFETs and impact ionization field-effect transistors, for example.

Although an embodiment of the present invention has been described with reference to a substantially vertically-aligned nanowire 2, the present invention is not limited thereto and any alternative configuration of the nanowire 2 is considered to be encompassed within the scope of the present invention. Furthermore, any nanowire of arbitrary shape, for example, circular, hexagonal, triangular, with a diameter on the order of 100 nm or less, and that is substantially longer, for example, at least ten times longer, in an axial direction as compared to a radial dimension such as the diameter of the nanowire is considered to be encompassed within the scope of the present invention.

In an embodiment of the present invention, the gate electrode 6 has been formed above the strain gate 7. However, the present invention is not limited to this configuration and a reverse configuration, i.e. with the strain gate 7 being formed above the gate electrode 6, is considered to be encompassed within the scope of the present invention, provided the criterion that the strain gate 7 is formed on the nanowire 2 to circumferentially surround the nanowire segment 8, which corresponds to the part of the channel region 5 that is disposed adjacent to the source region 3, is satisfied.

Although an embodiment of the present invention has been described hereinbefore with reference to the reduction of band-gap of the source region relative to that of the channel region and/or a reduction of the tunneling mass of the carriers, an embodiment of the present invention is not restricted thereto. Where an increase in the band-gap of the source relative to that of the channel region and/or an increase in tunneling mass of the carriers is desired due to a specific application, for example, this may be facilitated by an embodiment of the present invention.

The present invention has been described above purely by way of example and modifications of detail can be made within the scope of the invention.

Each feature disclosed in the description, and where appropriate, the claims and the drawings may be provided independently or in any appropriate combination.

1. A semiconductor device comprising:
a nanowire configured to comprise: a source region comprising a corresponding source semiconductor material, a drain region comprising a corresponding drain semiconductor material and a channel region comprising a corresponding channel semiconductor material, wherein the channel region is arranged between the source region and the drain region;
a gate electrode that is arranged relative to the nanowire to circumferentially surround at least a part of the channel region; and
a strain gate that is arranged relative to the nanowire to circumferentially surround at least a part of a segment of the nanowire, the strain gate being configured to apply a strain to the nanowire segment, to facilitate an alteration of the energy bands corresponding to the source region relative to the energy bands corresponding to the channel region

2. The semiconductor device of claim 1, wherein the strain gate is configurable to apply a strain gate bias to the nanowire segment, to facilitate electrostatic doping of the nanowire segment.

3. The semiconductor device of claim 1, wherein the strain gate comprises a material that is chosen to provide a specific strain value to the nanowire segment and to have a work-function value in accordance with a polarity of the semiconductor device.

4. The semiconductor device of claim 1, wherein the nanowire is vertically aligned.

5. The semiconductor device of claim 4, wherein a strain gate spacer layer is provided below the strain gate.

6. The semiconductor device of claim 1, wherein a gate dielectric is provided conformally on an outer surface of the nanowire.

7. The semiconductor device of claim 6, wherein the gate dielectric comprises a dielectric material having a dielectric constant relative to a vacuum that is greater in magnitude than 4.

8. The semiconductor device of claim 1, wherein the strain gate comprises a metal.

9. The semiconductor device of claim 1, wherein an isolation layer is provided between the gate electrode and the strain gate.

10. The semiconductor device of claim 1, wherein the source semiconductor material, the drain semiconductor material and the channel semiconductor material are the same.

11. The semiconductor device of claim 10, wherein the source semiconductor material, the drain semiconductor material and the channel semiconductor material comprise one of: a Group IV element and a binary compound.

12. The semiconductor device of claim 1, wherein the source semiconductor material is different from the channel semiconductor material.

13. The semiconductor device of claim 12, wherein the source semiconductor material comprises one of: a Group III-V material system, a binary, ternary and quaternary compound.

14. The semiconductor device of claim 1, wherein the semiconductor device comprises one of: a tunnel FET, a MOSFET and an impact ionization FET.

15. A method for fabricating a semiconductor device comprising the steps of:
providing a nanowire that is configured to comprise: a source region comprising a corresponding source semiconductor material, a drain region comprising a corresponding drain semiconductor material and a channel region comprising a corresponding channel semiconductor material, wherein the channel region is arranged between the source region and the drain region;
forming a gate electrode that is arranged relative to the nanowire to circumferentially surround at least a part of the channel region;
forming a strain gate that is arranged relative to the nanowire to circumferentially surround at least a part of a segment of the nanowire; and
configuring the strain gate to apply a strain to the nanowire segment, to facilitate an alteration of the energy bands corresponding to the source region relative to the energy bands corresponding to the channel region.

16. The method of claim 15, further comprising the step of configuring the strain gate to apply a strain gate bias to the nanowire segment to facilitate electrostatic doping of the nanowire segment.

17. The method of claim 15, wherein the strain gate is selected to comprise a material that is chosen to provide a specific strain value to the nanowire segment and to have a work-function value in accordance with a polarity of the semiconductor device.

18. The method of claim 15, wherein, in the step of providing the nanowire, the nanowire is vertically aligned.

19. The method of claim 18, further comprising the step of providing a strain gate spacer layer below the strain gate.

20. The method of claim 15, further comprising the step of providing a gate dielectric conformally on an outer surface of the nanowire.

21. The method of claim 20, wherein, in the step of providing the gate dielectric, the gate dielectric is selected to comprise a dielectric material having a dielectric constant relative to a vacuum that is greater in magnitude than 4.

22. The method of claim 15, wherein the strain gate comprises a metal.

23. The method of claim 15, further comprising the step of providing an isolation layer between the gate electrode and the strain gate.

24. The method of claim 15, wherein, in the step of providing the nanowire, the source semiconductor material, the drain semiconductor material and the channel semiconductor material are selected to be the same.

25. The method of claim 24, wherein the source semiconductor material, the drain semiconductor material and the channel semiconductor material are selected to comprise one of: a Group IV element and a binary compound.

26. The method of claim 15, wherein, in the step of providing the nanowire, the source semiconductor material is selected to be different from the channel semiconductor material.

27. The method of claim 26, wherein the source semiconductor material is selected to comprise one of: a Group III-V material system, a binary, ternary and quaternary compound.
